(19) United States
(12) Patent Application Publication
(10) Pub. No.: US 2019/0221781 A1
(43) Pub. Date: Jul. 18, 2019

(54) EVAPORATOR AND METHOD FOR ADJUSTING LEVELNESS OF EVAPORATOR

(71) Applicants: BOE Technology Group Co., Ltd., Beijing (CN); Ordos Yuansheng Optoelectronics Co., Ltd., Inner Mongolia (CN)

(72) Inventors: Chunchieh Huang, Beijing (CN); Chunsheng Gu, Beijing (CN); Xin Zhao, Beijing (CN)

(21) Appl. No.: 16/110,382

(22) Filed: Aug. 23, 2018

(30) Foreign Application Priority Data
Jan. 17, 2018 (CN) 201820080823.3

(51) Int. Cl. H01L 51/56; G01C 9/00; H01L 51/00; C23C 14/54; C23C 14/24; C23C 14/04

(52) U.S. Cl. CPC H01L 51/56; G01C 9/00; H01L 51/001; C23C 14/042; H01L 51/0012; C23C 14/54; C23C 14/24; H01L 51/0011

(57) ABSTRACT

An evaporator and a method for adjusting levelness of an evaporator are provided. The evaporator includes: a first platform; a second platform; a distance measuring assembly configured to measure a plurality of first distances between the first platform and a top of a vacuum chamber accommodating the evaporator, and/or a plurality of second distances between the first platform and the second platform; a driving assembly configured to drive the first platform and/or the second platform; and a data processing assembly electrically connected to the distance measuring assembly and the driving assembly, and configured to control the driving assembly to adjust levelness of the first platform according to the measured plurality of first distances, and/or to control the driving assembly to adjust levelness of the second platform according to the measured plurality of second distances.

### CROSS-REFERENCE TO RELATED APPLICATION

This application claims the priority benefit of Chinese Patent Application No. 201820080823.3 filed on Jan. 17, 2018 in the State Intellectual Property Office of China, the disclosure of which is incorporated herein by reference in entirety.

### BACKGROUND

### Technical Field

Embodiments of the present disclosure relate to the field of display device manufacturing technology or vapor deposition device technology, and in particular, to an evaporator and a method for adjusting levelness of an evaporator.

### Description of the Related Art

In the manufacture of an Organic Light-Emitting Diode (abbreviated as OLED), an organic light-emitting functional layer in OLED functional layers is manufactured by an evaporation of an organic material using an evaporator.

### SUMMARY

An embodiment of the present disclosure provides an evaporator, comprising:

a first platform;

a second platform;

a distance measuring assembly configured to measure a plurality of first distances between the first platform and a top of a vacuum chamber accommodating the evaporator, and/or a plurality of second distances between the first platform and the second platform;

a driving assembly configured to drive the first platform and/or the second platform; and

a data processing assembly electrically connected to the distance measuring assembly and the driving assembly, and configured to control the driving assembly to adjust levelness of the first platform according to the measured plurality of first distances, and/or to control the driving assembly to adjust levelness of the second platform according to the measured plurality of second distances.

In an example, the distance measuring assembly comprises:

a first distance measuring member disposed on the first platform and configured to measure the plurality of first distances between the first platform and the top of the vacuum chamber; and/or

a second distance measuring member disposed on the second platform and configured to measure the plurality of second distances between the first platform and the second platform.

In an example, the first platform comprises: an upper stage and a lower stage which are oppositely disposed; and a connection portion configured to connect the upper stage with the lower stage.

In an example, the first distance measuring member is disposed on a side of the upper stage close to the top of the vacuum chamber.

In an example, the second platform is disposed between the upper stage and the lower stage, and the second distance measuring member is disposed on a side of the second platform close to the upper stage.

In an example, the first distance measuring member comprises a plurality of first distance measuring sub-members, and/or the second distance measuring member comprises a plurality of second distance measuring sub-members.

In an example, the first distance measuring sub-members and the second distance measuring sub-members each comprise a distance sensor.

In an example, the data processing assembly comprises:

a data processing member configured to obtain a plurality of first correction distances according to the measured plurality of first distances, and/or obtain a plurality of second correction distances according to the measured plurality of second distances; and

a drive controlling member electrically connected to the data processing member and the driving assembly and configured to control the driving assembly to adjust the levelness of the first platform according to the plurality of first correction distances, and/or configured to control the driving assembly to adjust the levelness of the second platform according to the plurality of second correction distances.

In an example, the data processing assembly further comprises an amplifying member electrically connected to the data processing member and configured to amplify the measured plurality of first distances and to transmit the amplified plurality of first distances to the data processing member, and/or configured to amplify the measured plurality of second distances and to transmit the amplified plurality of second distances to the data processing member.

In an example, the data processing member is configured to acquire a first reference distance according to the measured plurality of first distances and then obtain the plurality of first correction distances according to the first reference distance and the plurality of first distances, and/or to acquire a second reference distance according to the measured plurality of second distances and then obtain the plurality of second correction distances according to the second reference distance and the plurality of second distances.

In an example, the first reference distance comprises an average value of the plurality of first distances or any one of the plurality of first distances.

In an example, the second reference distance comprises an average value of the plurality of second distances or any one of the plurality of second distances.

In an example, the driving assembly comprises: a motor, a first lead screw connected to the first platform, and a second lead screw connected to the second platform; and

wherein the data processing assembly is configured to control the motor to drive the first lead screw to adjust the levelness of the first platform, and/or to control the motor to drive the second lead screw to adjust the levelness of the second platform.

In an example, the motor comprises a servo motor.

An embodiment of the present disclosure further provides a method for adjusting levelness of an evaporator, the evaporator comprising: a first platform; a second platform; a distance measuring assembly; a driving assembly; and a data processing assembly, wherein the method comprises:

measuring a plurality of first distances between the first platform and a top of a vacuum chamber accommodating the evaporator, and/or a plurality of second distances between the first platform and the second platform, by the distance measuring assembly; and

controlling the driving assembly to adjust levelness of the first platform according to the measured plurality of first distances, and/or controlling the driving assembly to adjust levelness of the second platform according to the measured plurality of second distances.

In an example, controlling the driving assembly to adjust the levelness of the first platform according to the measured plurality of first distances comprises:

obtaining a plurality of first correction distances according to the measured plurality of first distances; and

controlling the driving assembly to adjust the levelness of the first platform according to the according to the plurality of first correction distances.

In an example, obtaining the plurality of first correction distances according to the measured plurality of first distances comprises:

acquiring a first reference distance according to the measured plurality of first distances; and

obtaining the plurality of first correction distances according to the first reference distance and the plurality of first distances.

In an example, controlling the driving assembly to adjust the levelness of the second platform according to the measured plurality of second distances comprises:

obtaining a plurality of second correction distances according to the measured plurality of second distances; and

controlling the driving assembly to adjust the levelness of the second platform according to the plurality of second correction distances.

In an example, obtaining the plurality of second correction distances according to the measured plurality of second distances comprises:

acquiring a second reference distance according to the measured plurality of second distances; and

obtaining the plurality of second correction distances according to the second reference distance and the plurality of second distances.

In an example, the method further comprises:

amplifying the plurality of first distances; and/or

amplifying the plurality of second distances.

Obviously, it does not necessarily require implementing all of the technical means described above to achieve any of the products or methods of the present disclosure.

Other features and advantages of the present disclosure will be described in the following embodiments of the specification, and they will be at least partially obvious from the embodiments of the specification or can be learned from implementing the embodiments of the present disclosure. The objectives and other advantages of the embodiments of the present disclosure can be realized and obtained by the structures particularly pointed out in the specification, the claims and the drawings.

### BRIEF DESCRIPTION OF THE DRAWINGS

The drawings are used to provide further understanding of the technical solutions of the embodiments of the present disclosure, and constitute a part of the present disclosure. They are intended to interpret the technical solutions of the present disclosure, but do not limit the technical solutions of the present disclosure.

FIG. 1 is a structural block diagram of an evaporator according to an embodiment of the present disclosure;

FIG. 2 is a schematic structural view of an evaporator according to an embodiment of the present disclosure;

FIG. 3 is a schematic structural view of an evaporator according to an embodiment of the present disclosure;

FIG. 4 is a schematic structural view of an evaporator according to an embodiment of the present disclosure;

FIG. 5 is a structural block diagram of a data processing assembly according to an embodiment of the present disclosure;

FIG. 6 is a structural block diagram of a data processing assembly according to an embodiment of the present disclosure; and

FIG. 7 is a flowchart of a method for adjusting levelness of an evaporator according to an embodiment of the present disclosure.

### DETAILED DESCRIPTION OF EMBODIMENTS

In order to more clearly set forth the purpose, technical solutions and advantages of the present disclosure, the embodiments of the present disclosure will be described in detail below with reference to the accompanying drawings. It should be noted that the embodiments of the present disclosure and the features in the embodiments may be arbitrarily combined with each other unless they contradicted with each other.

The steps shown in the flowcharts of the drawings may be performed in a computer system including, for example, a set of computer executable instructions. Also, although logical sequences are shown in the flowcharts, in some cases the steps shown or described may be performed in a different order rather than the ones described herein.

Unless otherwise defined, technical terms or scientific terms used in the embodiments of the present disclosure should be understood in terms of ordinary meaning by those skilled in the art. The terms “first”, “second” and the like used in the embodiments of the present disclosure do not denote any order, quantity, or importance, but they are merely used to distinguish different components. The words “include”, “comprise”, or the like are intended to mean that the elements or items that are present in front of such words cover the elements or items and equivalents thereof listed behind such words, without excluding other elements or items. The words “connect” or “join” and the like are not limited to physical or mechanical connections, but may include electrical connections, whether direct or indirect. “Upper”, “lower”, “left”, “right”, and the like are only used to indicate relative positional relationships, and when an absolute position of the described object is changed, these relative positional relationships may also change accordingly.

An evaporator mainly comprises a first platform for receiving a substrate and a second platform for receiving a mask, and the working principle thereof refers to that an organic material to be evaporated is evaporated and deposited on the substrate through the mask.

In consideration of the demand of mass production of OLEDs, the evaporator is frequently moved during an evaporation process, which leads to a deviation of the levelness of the platform in the evaporator, an occurrence of mask offset and a problem of unsuccessful alignment. As a result, mass production speed and stability of the OLEDs are adversely affected.

According to the research of the designer, the adjustment of the levelness of the evaporator in related art requires cooling down the evaporator, removing vacuum state and then manually adjusting the levelness of the platform, by an operator in production and maintenance. Therefore, it cannot adjust the levelness of the platform of the evaporator in real time, and adjustment accuracy is not high.

In order to at least partially solve the above technical problems, the embodiments of the present disclosure provide an evaporator by which it can not only adjust the levelness of the platform of the evaporator in real time, but also improve the adjustment accuracy.

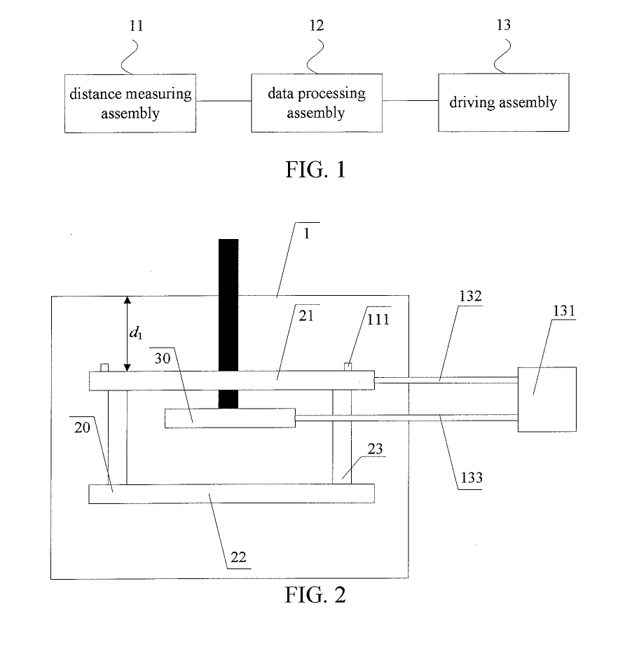

FIG. 1 is a structural block diagram of an evaporator according to an embodiment of the present disclosure. As shown in FIG. 1, the embodiment of the present disclosure provides an evaporator, including: a first platform, a second platform, a distance measuring assembly 11, a data processing assembly 12, and a driving assembly 13.

In this embodiment, the distance measuring assembly 11 is configured to measure a plurality of first distances between the first platform and a top of a vacuum chamber accommodating the evaporator, and/or a plurality of second distances between the first platform and the second platform; the driving assembly 13 is configured to drive the first platform and/or the second platform; the data processing assembly 12 is electrically connected to the distance measuring assembly 11 and the driving assembly 13 configured to control the driving assembly to adjust levelness of the first platform according to the measured plurality of first distances, and/or controlling the driving assembly to adjust levelness of the second platform according to the measured plurality of second distances.

Specifically, the first platform is configured to receive a substrate to be evaporated, and the second platform is disposed in the first platform and configured to receive a mask. An evaporation source for evaporating an evaporation material is disposed in the first platform, and is configured to perform an evaporation process to the substrate to be processed by a mask.

In an example, the number of the first distances and the number of the second distances may be same or different from each other, and the number of the first distances and the number of the second distances will not be limited in the embodiments of the present disclosure.

The embodiment of the present disclosure provides an evaporator, including: a first platform, a second platform, a distance measuring assembly, a data processing assembly, and a driving assembly. The distance measuring assembly is configured to measure a plurality of first distances between the first platform and a top of a vacuum chamber accommodating the evaporator, and/or a plurality of second distances between the first platform and the second platform; the driving assembly is configured to drive the first platform and/or the second platform; the data processing assembly is electrically connected to the distance measuring assembly and the driving assembly and configured to control the driving assembly to adjust levelness of the first platform according to the measured plurality of first distances, and/or configured to control the driving assembly to adjust levelness of the second platform according to the measured plurality of second distances. The embodiment of the present disclosure automatically adjusts the levelness of the first platform and/or the second platform according to the measured distances, therefore it can not only adjust the levelness of the platform of the evaporator in real time, but also improve the adjustment accuracy.

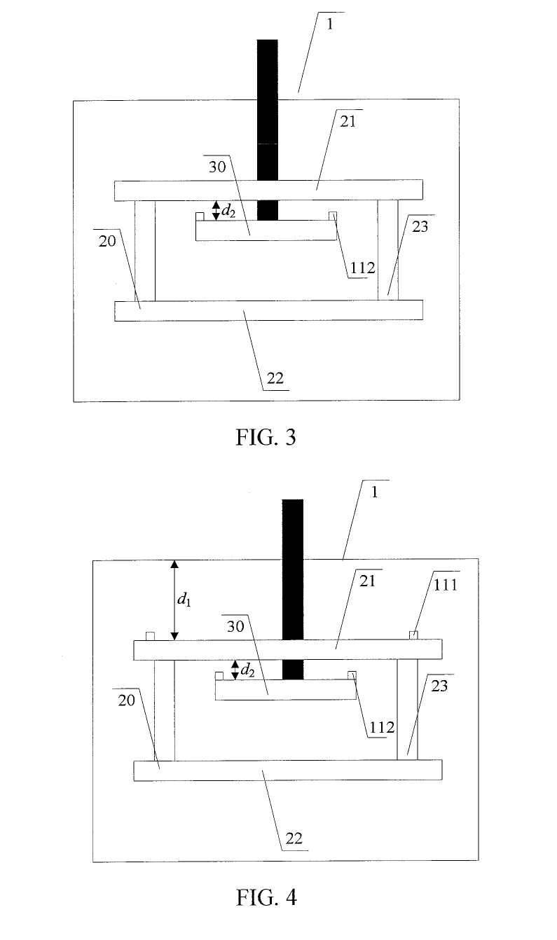

In an example, FIG. 2 is a schematic structural view of an evaporator according to an embodiment of the present disclosure. FIG. 3 is a schematic structural view of an evaporator according to another embodiment of the present disclosure. FIG. 4 is a schematic structural view of an evaporator according to a further embodiment of the present disclosure. As shown in FIGS. 2-4, the evaporator according to the embodiments of the present disclosure includes a first platform 20 and a second platform 30, and the evaporator is placed in a vacuum chamber 1.

In an example, the distance measuring assembly 11 comprises a first distance measuring member 111 and/or a second distance measuring member 112.

It should be noted that, FIG. 2 shows an example in which the distance measuring assembly includes the first distance measuring member 111, FIG. 3 shows an example in which the distance measuring assembly includes the second distance measuring member 112, and FIG. 4 shows an example in which the distance measuring assembly includes the first distance measuring member 111 and the second distance measuring member 112.

In an example, the first distance measuring member 111 is disposed on the first platform 20 and configured to measure the plurality of first distances di between the first platform 20 and the top of the vacuum chamber 1.

In an example, the first distance measuring member 111 includes a plurality of first distance measuring sub-members.

Specifically, in order to ensure the accuracy of the adjustment for levelness, four first distance measuring sub-members are provide in the embodiment of the present disclosure, and the first distance measuring sub-members are disposed in four corners of the first platform 20, for example, four corners of an upper surface of the first platform.

In an example, the second distance measuring member 112 is disposed on the second platform 30 and configured to measure the plurality of second distances d₂ between the first platform 20 and the second platform 30.

In an example, the second distance measuring member 112 includes a plurality of second distance measuring sub-members.

Specifically, in order to ensure the accuracy of the adjustment for levelness, four second distance measuring sub-members are provide in the embodiment of the present disclosure, and the second distance measuring sub-members are disposed in four corners of the second platform 30, for example, four corners of an upper surface of the second platform.

In an example, the first distance measuring sub-members and the second distance measuring sub-members each include a distance sensor, or other devices capable of measuring distance, which is not limited in the present disclosure.

In an example, the first platform 20 includes: an upper stage 21 and a lower stage 22 which are oppositely disposed, and a connection portion 23 configured to connect the upper stage 21 with the lower stage 22.

In an example, the second platform 30 is a hollow square frame configured to receive the mask.

It should be noted that the substrate to be processed is disposed on a side of the upper stage 21 close to the lower stage 22, the mask is disposed on the second platform 30, and the evaporation source is disposed on a side of the lower stage 22 close to the upper stage 21. In addition, the connection portion 23 may be columnar or may be of other shapes, and the present disclosure will not specifically define the shape of the connection portion.

In an example, the first distance measuring member 111 is disposed on a side of the upper stage 21 close to the top of the vacuum chamber 1.

In an example, the second platform 30 is disposed between the upper stage 21 and the lower stage 22, and the second distance measuring member 112 is disposed on a side of the second platform 30 close to the upper stage 21.

In this embodiment, by means of simultaneously adjusting the levelness of the first platform and the second platform, the utilization rate of equipment can be improved, the success rate of substrate alignment can be improved, the fragmentation rate can be reduced, and eventually the productivity can be improved.

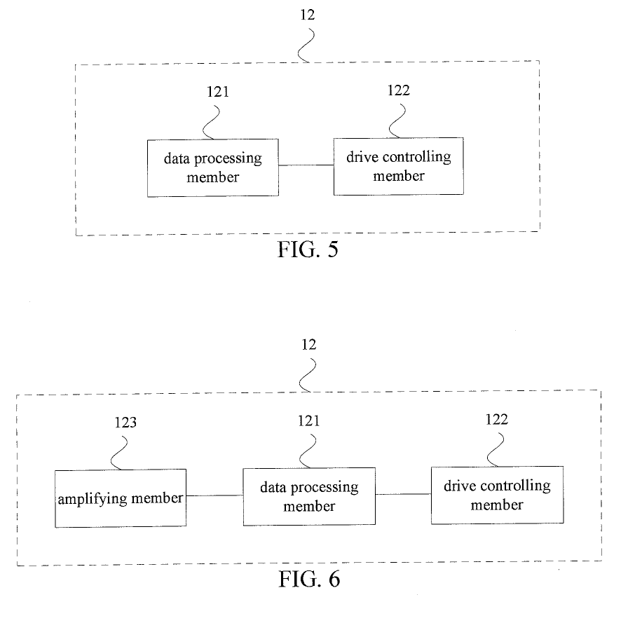

In an example, FIG. 5 is a structural block diagram of a data processing assembly according to an embodiment of the present disclosure. As shown in FIG. 5, the data processing assembly 12 according to the embodiment of the present disclosure includes a data processing member 121 and a drive controlling member 122.

In this embodiment, the data processing assembly 121 is configured to obtain a plurality of first correction distances according to the measured plurality of first distances, and/or obtain a plurality of second correction distances according to the measured plurality of second distances. The drive controlling member 122 is electrically connected to the data processing member 121 and the driving assembly configured to control the driving assembly to adjust the levelness of the first platform according to the plurality of first correction distances, and/or configured to control the driving assembly to adjust the levelness of the second platform according to the plurality of second correction distances.

In an example, the data processing assembly 121 is specifically configured to acquire a first reference distance according to the measured plurality of first distances and then obtain the plurality of first correction distances according to the first reference distance and the plurality of first distances, and/or to acquire a second reference distance according to the measured plurality of second distances and then obtain the plurality of second correction distances according to the second reference distance and the plurality of second distances.

In an example, the first reference distance includes an average value of the plurality of first distances or any one of the plurality of first distances.

In an example, the second reference distance includes an average value of the plurality of second distances or any one of the plurality of second distances.

Specifically, in this embodiment, the data processing assembly 121 calculates an average value of the plurality of first distances as the first reference distance according to the measured plurality of first distances, and then obtains the plurality of first correction distances according to the first reference distance and the plurality of first distances; or selects any one of the first distances as the first reference distance according to the measured plurality of first distances, and then obtains the plurality of first correction distances according to the first reference distance and the plurality of first distances.

In this embodiment, the data processing assembly 121 calculates an average value of the plurality of second distances as the second reference distance according to the measured plurality of second distances, and then obtains the plurality of second correction distances according to the second reference distance and the plurality of second distances; or selects any one of the second distances as the second reference distance according to the measured plurality of second distances, and then obtains the plurality of second correction distances according to the second reference distance and the plurality of second distances.

In an example, the data processing member 121 includes a Programmable Logic Controller (abbreviated as PLC).

In an example, the drive controlling member 122 includes a servo amplifier.

In an example, FIG. 6 is a structural block diagram of a data processing assembly according to an embodiment of the present disclosure. As shown in FIG. 6, the data processing assembly 12 further includes an amplifying member 123.

In this embodiment, the amplifying member 123 is electrically connected to the data processing member 121 configured to amplify the measured plurality of first distances and transmitting the amplified plurality of first distances to the data processing member, and/or amplifying the measured plurality of second distances and transmitting the amplified plurality of second distances to the data processing member.

In an example, the amplifying member 123 includes an amplifier.

In this embodiment, by means of amplifying the measured plurality of first distances and/or the measured plurality of second distances, the sensitivity of the automatic adjustment of the evaporator can be improved.

In an example, the driving assembly 13 includes a motor 131, a first lead screw 132 connected to the first platform, and a second lead screw 133 connected to the second platform. The data processing assembly is specifically configured to control the motor 131 to drive the first lead screw 132 to adjust the levelness of the first platform; and/or configured to control the motor 131 to drive the second lead screw 133 to adjust the levelness of the second platform.

The motor 131 is connected to the first lead screw 132 and the second lead screw 133.

In an example, the motor 131 includes a servo motor.

The working principle of the evaporator will be further described below by taking the distance measuring assembly in the evaporator including the first distance measuring member and the second distance measuring member as an example.

When the evaporator is placed in the vacuum chamber to perform an evaporation process to the substrate to be processed, the first distance measuring member measures the plurality of first distances between the first platform and the top of the vacuum chamber in real time, the data processing member acquires the first reference distance according to the measured plurality of first distances and then obtains the plurality of first correction distances according to the first reference distance and the plurality of first distances, and the drive controlling member controls the servo motor to drive the first lead screw to adjust the levelness of the first platform according to the plurality of first correction distances; the second distance measuring member measures the plurality of second distances between the first platform and the second platform in real time, the data processing member acquires the second reference distance according to the measured plurality of second distances and then obtains the plurality of second correction distances according to the second reference distance and the plurality of second distances, and the drive controlling member controls the servo motor to drive the second lead screw to adjust the levelness of the second platform according to the plurality of second correction distances.

It should be noted that the above working principle is described by taking the distance measuring assembly including the first distance measuring member and the second distance measuring member as an example. It is possible that the distance measuring assembly only includes the first distance measuring member or the second distance measuring member, so as to adjust the levelness of the first platform or the second platform, which will not be described again in the present disclosure.

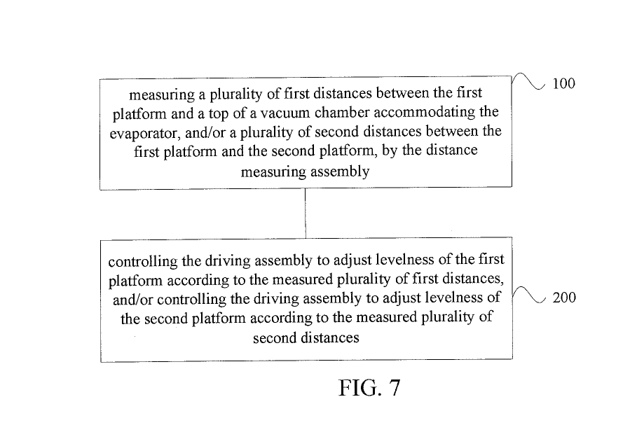

Based on the concept of the above embodiments, an embodiment of the present disclosure further provides a method for adjusting levelness of an evaporator, which is applied to the evaporator according to the above embodiments. Specifically, the evaporator includes: a first platform, a second platform, a distance measuring assembly, a data processing assembly, and a driving assembly. FIG. 7 is a flowchart of the method for adjusting the levelness of the evaporator according to the embodiment of the present disclosure, as shown in FIG. 7, the method for adjusting the levelness of the evaporator according to the embodiment of the present disclosure includes:

Step 100: Measuring a plurality of first distances between the first platform and the top of the vacuum chamber, and/or a plurality of second distances between the first platform and the second platform.

In an example, the number of the first distances and the number of the second distances may be same or different from each other, and the number of the first distances and the number of the second distances will not be limited in the embodiments of the present disclosure.

Step 200: Controlling the driving assembly to adjust the levelness of the first platform according to the measured plurality of first distances, and/or controlling the driving assembly to adjust levelness of the second platform according to the measured plurality of second distances.

In the method for adjusting the levelness of the evaporator according to the embodiment of the present disclosure, applied to the evaporator, it specifically includes: measuring a plurality of first distances between the first platform and the top of the vacuum chamber, and/or a plurality of second distances between the first platform and the second platform; and controlling the driving assembly to adjust the levelness of the first platform according to the measured plurality of first distances, and/or controlling the driving assembly to adjust levelness of the second platform according to the measured plurality of second distances. The embodiment of the present disclosure automatically adjusts the levelness of the first platform and/or the second platform according to the measured distances, therefore it can not only adjust the levelness of the platform of the evaporator in real time, but also improve the adjustment accuracy.

In an example, in the step 200, controlling the driving assembly to adjust the levelness of the first platform according to the measured plurality of first distances includes: obtaining a plurality of first correction distances according to the measured plurality of first distances; and controlling the driving assembly to adjust the levelness of the first platform according to the plurality of first correction distances.

In an example, obtaining the plurality of first correction distances according to the measured plurality of first distances includes: acquiring a first reference distance according to the measured plurality of first distances; and obtaining the plurality of first correction distances according to the first reference distance and the plurality of first distances.

In an example, the first reference distance includes an average value of the plurality of first distances or any one of the plurality of first distances.

In an example, in the step 200, controlling the driving assembly to adjust the levelness of the second platform according to the measured plurality of second distances includes: obtaining a plurality of second correction distances according to the measured plurality of second distances; and controlling the driving assembly to adjust the levelness of the second platform according to the plurality of second correction distances.

In an example, obtaining the plurality of second correction distances according to the measured plurality of second distances includes: acquiring a second reference distance according to the measured plurality of second distances; and obtaining the plurality of second correction distances according to the second reference distance and the plurality of second distances.

In an example, the second reference distance includes an average value of the plurality of second distances or any one of the plurality of second distances.

In an example, before acquiring the first reference distance according to the measured plurality of first distances, the method according to the embodiment of the present disclosure further includes: amplifying the plurality of first distances.

In an example, before acquiring the second reference distance according to the measured plurality of second distances, the method according to the embodiment of the present disclosure further includes: amplifying the plurality of second distances.

The embodiments disclosed in the present disclosure are as described above, however they are merely used to facilitate the understanding of the present disclosure, and are not intended to limit the present disclosure. Modification and variation in the forms and details of the embodiments may be made by those skilled in the art without departing from the spirit and scope of the present disclosure. The scope of the present disclosure is defined by the appended claims and equivalents thereof.

What is claimed is:

1. An evaporator, comprising:
a first platform;
a second platform;
a distance measuring assembly configured to measure a plurality of first distances between the first platform and a top of a vacuum chamber accommodating the evaporator, and/or a plurality of second distances between the first platform and the second platform;
a driving assembly configured to drive the first platform and/or the second platform; and
a data processing assembly electrically connected to the distance measuring assembly and the driving assembly, and configured to control the driving assembly to adjust levelness of the first platform according to the measured plurality of first distances, and/or to control the driving assembly to adjust levelness of the second platform according to the measured plurality of second distances.

2. The evaporator according to claim 1, wherein the distance measuring assembly comprises:
a first distance measuring member disposed on the first platform and configured to measure the plurality of first distances between the first platform and the top of the vacuum chamber; and/or
a second distance measuring member disposed on the second platform and configured to measure the plurality of second distances between the first platform and the second platform.

3. The evaporator according to claim 2, wherein the first platform comprises: an upper stage and a lower stage which are oppositely disposed; and a connection portion configured to connect the upper stage with the lower stage.

4. The evaporator according to claim 3, wherein the first distance measuring member is disposed on a side of the upper stage close to the top of the vacuum chamber.

5. The evaporator according to claim 3, wherein the second platform is disposed between the upper stage and the lower stage, and the second distance measuring member is disposed on a side of the second platform close to the upper stage.

6. The evaporator according to claim 2, wherein the first distance measuring member comprises a plurality of first distance measuring sub-members, and/or the second distance measuring member comprises a plurality of second distance measuring sub-members.

7. The evaporator according to claim 6, wherein the first distance measuring sub-members and the second distance measuring sub-members each comprise a distance sensor.

8. The evaporator according to claim 1, wherein the data processing assembly comprises:
a data processing member configured to obtain a plurality of first correction distances according to the measured plurality of first distances, and/or obtain a plurality of second correction distances according to the measured plurality of second distances; and
a drive controlling member electrically connected to the data processing member and the driving assembly and configured to control the driving assembly to adjust the levelness of the first platform according to the plurality of first correction distances, and/or configured to control the driving assembly to adjust the levelness of the second platform according to the plurality of second correction distances.

9. The evaporator according to claim 8, wherein the data processing assembly further comprises an amplifying member electrically connected to the data processing member and configured to amplify the measured plurality of first distances and to transmit the amplified plurality of first distances to the data processing member, and/or configured to amplify the measured plurality of second distances and to transmit the amplified plurality of second distances to the data processing member.

10. The evaporator according to claim 8, wherein the data processing member is configured to acquire a first reference distance according to the measured plurality of first distances and then obtain the plurality of first correction distances according to the first reference distance and the plurality of first distances, and/or to acquire a second reference distance according to the measured plurality of second distances and then obtain the plurality of second correction distances according to the second reference distance and the plurality of second distances.

11. The evaporator according to claim 10, wherein the first reference distance comprises an average value of the plurality of first distances or any one of the plurality of first distances.

12. The evaporator according to claim 10, wherein the second reference distance comprises an average value of the plurality of second distances or any one of the plurality of second distances.

13. The evaporator according to claim 1, wherein the driving assembly comprises:
a motor, a first lead screw connected to the first platform, and a second lead screw connected to the second platform; and
wherein the data processing assembly is configured to control the motor to drive the first lead screw to adjust the levelness of the first platform, and/or to control the motor to drive the second lead screw to adjust the levelness of the second platform.

14. The evaporator according to claim 13, wherein the motor comprises a servo motor.

15. A method for adjusting levelness of an evaporator, the evaporator comprising: a first platform; a second platform; a distance measuring assembly; a driving assembly; and a data processing assembly, wherein the method comprises:
measuring a plurality of first distances between the first platform and a top of a vacuum chamber accommodating the evaporator, and/or a plurality of second distances between the first platform and the second platform, by the distance measuring assembly; and
controlling the driving assembly to adjust levelness of the first platform according to the measured plurality of first distances, and/or controlling the driving assembly to adjust levelness of the second platform according to the measured plurality of second distances.

16. The method according to claim 15, wherein controlling the driving assembly to adjust the levelness of the first platform according to the measured plurality of first distances comprises:
obtaining a plurality of first correction distances according to the measured plurality of first distances; and
controlling the driving assembly to adjust the levelness of the first platform according to the according to the plurality of first correction distances.

17. The method according to claim 16, wherein obtaining the plurality of first correction distances according to the measured plurality of first distances comprises:
acquiring a first reference distance according to the measured plurality of first distances; and
obtaining the plurality of first correction distances according to the first reference distance and the plurality of first distances.

18. The method according to claim 15, wherein controlling the driving assembly to adjust the levelness of the second platform according to the measured plurality of second distances comprises:
obtaining a plurality of second correction distances according to the measured plurality of second distances; and
controlling the driving assembly to adjust the levelness of the second platform according to the plurality of second correction distances.

19. The method according to claim 18, wherein obtaining the plurality of second correction distances according to the measured plurality of second distances comprises:
acquiring a second reference distance according to the measured plurality of second distances; and
obtaining the plurality of second correction distances according to the second reference distance and the plurality of second distances.

20. The method according to claim 15, wherein the method further comprises:
amplifying the plurality of first distances; and/or
amplifying the plurality of second distances.
